(19) United States
(12) Patent Application Publication
(10) Pub. No.: US 2026/0113947 A1
(43) Pub. Date: Apr. 23, 2026

(54) THREE-DIMENSIONAL NAND MEMORY AND FABRICATION METHOD THEREOF

(71) Applicant: YANGTZE MEMORY TECHNOLOGIES CO., LTD., Wuhan (CN)

(72) Inventors: Yuancheng YANG, Wuhan (CN); Lei LIU, Wuhan (CN); Wenxi ZHOU, Wuhan (CN)

(21) Appl. No.: 19/427,605

(22) Filed: Dec. 19, 2025

Related U.S. Application Data
(62) Division of application No. 17/566,352, filed on Dec. 30, 2021.
Application No. 17/566,352 is a continuation of application No. PCT/CN2021/130534, filed on Nov. 15, 2021.

(30) Foreign Application Priority Data
May 6, 2021 (CN) 202110490025.4

(51) Int. Cl. H10B 43/27; G11C 16/04; H10B 41/10; H10B 41/27; H10B 41/35; H10B 43/10; H10B 43/35

(52) U.S. Cl. CPC H10B 43/27; G11C 16/0483; H10B 41/10; H10B 41/27; H10B 41/35; H10B 43/10; H10B 43/35

(57) ABSTRACT

The present disclosure provides a method for forming a three-dimensional (3D) memory device. The method includes disposing an alternating dielectric stack that includes first dielectric layers and second dielectric layers alternatingly stacked on the substrate; forming a channel structure penetrating through the alternating dielectric stack in a first direction perpendicular to the substrate. The channel structure includes a charge trapping layer extending in the first direction. The method also includes removing at least one second dielectric layer at a top portion of the alternating dielectric stack to form a top select gate (TSG) cut tunnel and to expose a portion of the charge trapping layer in a second direction parallel to the substrate. The method further includes removing the exposed portion of the charge trapping layer inside the TSG cut tunnel; and disposing a TSG conductive layer inside the TSG cut tunnel.

### INCORPORATION BY REFERENCE

This application is a divisional of U.S. application Ser. No. 17/566,352, filed on Dec. 30, 2021, which is a continuation of International Application No. PCT/CN2021/130534, filed on Nov. 15, 2021, which application claims priority to Chinese Patent Application No. 202110490025.4, filed on May 6, 2021, which is incorporated herein by reference in its entirety.

### TECHNICAL FIELD

The present disclosure generally relates to the field of semiconductor technology, and more particularly, to a three-dimensional memory and its fabrication methods.

### BACKGROUND

As memory devices are shrinking to smaller die size to reduce manufacturing cost and increase storage density, scaling of planar memory cells faces challenges due to process technology limitations and reliability issues. A three-dimensional (3D) memory architecture can address the density and performance limitation in planar memory cells.

In a 3D NAND flash memory, a memory array can include a plurality of memory strings vertically arranged on a substrate, each memory string having a plurality of memory cells that are vertically stacked on top of each other. As such, storage density per unit area can be greatly increased. To perform program, read and erase operations, each memory string can be electrically connected to an array common source at one end and connected to a bit line at another end. A top select transistor located at the top of each memory string can be switched on or off through a top select gate so as to control the electrical connection between the memory string and the bit line.

### BRIEF SUMMARY

Embodiments of a three-dimensional (3D) memory device and a method for forming the same are described in the present disclosure.

One aspect of the present disclosure provides a method for forming a three-dimensional (3D) memory device. The method includes the following steps: forming an alternating dielectric stack that includes alternately stacked dielectric layers and sacrificial layers on a substrate; forming a channel hole penetrating the alternating dielectric stack, and sequentially disposing a memory film and a channel layer on a sidewall of the channel hole to form a channel structure; forming a top select gate (TSG) cut opening through at least one of the sacrificial layer; through the TSG cut opening, sequentially removing the at least one sacrificial layer and a portion of the memory film corresponding to the at least one sacrificial layer to form a TSG cut tunnel; and disposing a TSG dielectric layer on an inner wall of the TSG cut tunnel, and a TSG conductive layer on the TSG dielectric layer inside the TSG cut tunnel.

In some embodiments, the disposing the TSG dielectric layer and the TSG conductive layer includes disposing silicon oxide and doped polysilicon, respectively.

In some embodiments, the forming the channel structure also includes forming an epitaxial plug at a bottom of the channel hole; forming the memory film on the sidewall of the channel hole and a surface of the epitaxial plug that is farther away from the substrate; and forming the channel layer on a sidewall of the memory film to contact the epitaxial plug.

In some embodiments, the method further includes, after the forming the channel structure, disposing a core filling film on the channel layer inside the channel hole; and forming a channel top plug in contact with the channel layer at an end of the core filling film that is farther away from the substrate.

In some embodiments, the method further includes, after the forming the channel structure, forming a capping layer to cover surfaces of the channel structure and the alternating dielectric stack that are farther away from the substrate.

In some embodiments, the forming the TSG cut opening also includes forming the TSG cut opening that penetrates through the capping layer and at least one of the sacrificial layer, and extends to a top of the dielectric layer.

In some embodiments, the disposing the TSG dielectric layer and the TSG conductive layer inside the TSG cut tunnel includes sequentially depositing the TSG dielectric layer and the TSG conductive layer on a sidewall of the TSG cut opening; and removing the TSG dielectric layer and the TSG conductive layer from the sidewall of the TSG cut opening.

In some embodiments, the method also includes filling the TSG cut opening with a dielectric material to form a TSG cut.

In some embodiments, the method also includes forming a gate line slit (GLS) opening that penetrates through the alternating dielectric stack and extends into the substrate; removing the sacrificial layers of the alternating dielectric stack through the GLS opening to form lateral tunnels; filling the lateral tunnels with a conductive material to form second conductive layers; and filling the GLS opening with a conductive material to form a GLS.

Another aspect of the present disclosure provides a three-dimensional (3D) memory. The 3D memory includes a substrate; a film stack of alternating conductive and dielectric layers disposed on the substrate that includes a top stack having alternately stacked TSG conductive layers and third dielectric layers, and a bottom stack having alternately stacked second conductive layers and first dielectric layers; a TSG dielectric layer between the TSG conductive layers and the third dielectric layers, and at least partially surrounding the TSG conductive layers; and a memory string that penetrates through the film stack of alternating conductive and dielectric layers and includes a channel layer and a memory film from inside to outside along a radial direction of the memory string. The TSG dielectric layer penetrates through the memory film in a direction parallel to the substrate and is in contact with the channel layer. The 3D memory includes a top select transistor at an intersection of the TSG conductive layer, the TSG dielectric layer and the channel layer.

In some embodiments, the TSG dielectric layer is silicon oxide and the TSG conductive layer is doped polycrystalline silicon.

In some embodiments, the memory string further includes an epitaxial plug that is close to and in contact with the substrate. The memory film extends onto a top surface of the epitaxial plug that is farther away from the substrate, where a portion of the top surface of the epitaxial plug is exposed. The channel layer extends onto the top surface of the epitaxial plug and is in contact with the exposed portion of the epitaxial plug.

In some embodiments, the 3D memory also includes a channel top plug located at an end of the memory string that is farther away from the substrate. The channel top plug is in contact with the channel layer.

In some embodiments, the 3D memory also includes a capping layer disposed on a top surface of the top stack that is farther away from the substrate. The capping layer covers the memory string.

In some embodiments, the 3D memory also includes a TSG cut penetrating through the top stack.

In some embodiments, the 3D memory also includes a gate line slit (GLS) penetrating through the film stack of alternating conductive and dielectric layers.

Other aspects of the present disclosure can be understood by those skilled in the art in light of the description, the claims, and the drawings of the present disclosure.

### BRIEF DESCRIPTION OF THE DRAWINGS

The accompanying drawings, which are incorporated herein and form a part of the specification, illustrate embodiments of the present disclosure and, together with the description, further serve to explain the principles of the present disclosure and to enable a person skilled in the pertinent art to make and use the present disclosure.

FIG. 1 illustrates a schematic top-down view of an exemplary three-dimensional (3D) memory die, according to some embodiments of the present disclosure.

FIG. 2 illustrates a schematic top-down view of a region of 3D memory die, according to some embodiments of the present disclosure.

FIG. 3 illustrates a perspective view of a portion of an exemplary 3D memory array structure, in accordance with some embodiments of the present disclosure.

FIG. 4 illustrates a method for forming a 3D memory device, according to some embodiments of the present disclosure.

FIG. 5-12 illustrate cross-sectional views of 3D memory structures at certain process step, according to some embodiments of the present disclosure.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

Embodiments of the present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other embodiments whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer there between. Moreover, “above” or “over” not only means “above” or “over” something, but can also include the meaning it is “above” or “over” something with no intermediate feature or layer there between (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, there above, and/or there below. A layer can include multiple layers. For example, an interconnect layer can include one or more conductive and contact layers (in which contacts, interconnect lines, and/or vertical interconnect accesses (VIAs) are formed) and one or more dielectric layers.

In the present disclosure, for ease of description, “tier” is used to refer to elements of substantially the same height along the vertical direction. For example, a word line and the underlying gate dielectric layer can be referred to as “a tier,” a word line and the underlying insulating layer can together be referred to as “a tier,” word lines of substantially the same height can be referred to as “a tier of word lines”or similar, and so on.

As used herein, the term “nominal/nominally” refers to a desired, or target, value of a characteristic or parameter for a component or a process step, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

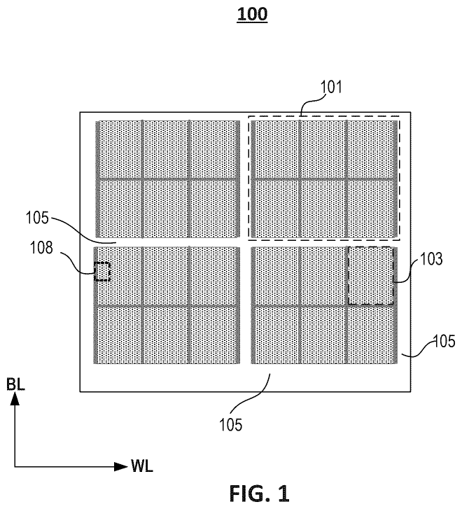

FIG. 1 illustrates a top-down view of an exemplary three-dimensional (3D) memory device 100, according to some embodiments of the present disclosure. The 3D memory device 100, such as 3D NAND Flash memory, can be a memory chip (package), a memory die or any portion of a memory die, and can include one or more memory planes 101, each of which can include a plurality of memory blocks 103. Identical and concurrent operations can take place at each memory plane 101. The memory block 103, which can be megabytes (MB) in size, is the smallest size to carry out erase operations. Shown in FIG. 1, the exemplary 3D memory device 100 includes four memory planes 101 and each memory plane 101 includes six memory blocks 103. Each memory block 103 can include a plurality of memory cells, where each memory cell can be addressed through interconnections such as bit lines and word lines. The bit lines and word lines can be laid out perpendicularly (e.g., in rows and columns, respectively), forming an array of metal lines. The direction of bit lines and word lines are labeled as “BL” and “WL” in FIG. 1. In this disclosure, memory block 103 is also referred to as a “memory array” or “array. ” The memory array is the core area in a memory device, performing storage functions.

The 3D memory device 100 also includes a periphery region 105, an area surrounding memory planes 101. The periphery region 105 contains many digital, analog, and/or mixed-signal circuits to support functions of the memory array, for example, page buffers, row and column decoders and sense amplifiers. Peripheral circuits use active and/or passive semiconductor devices, such as transistors, diodes, capacitors, resistors, etc., as would be apparent to a person of ordinary skill in the art.

It is noted that, the arrangement of the memory planes 101 in the 3D memory device 100 and the arrangement of the memory blocks 103 in each memory plane 101 illustrated in FIG. 1 are only used as an example, which does not limit the scope of the present disclosure.

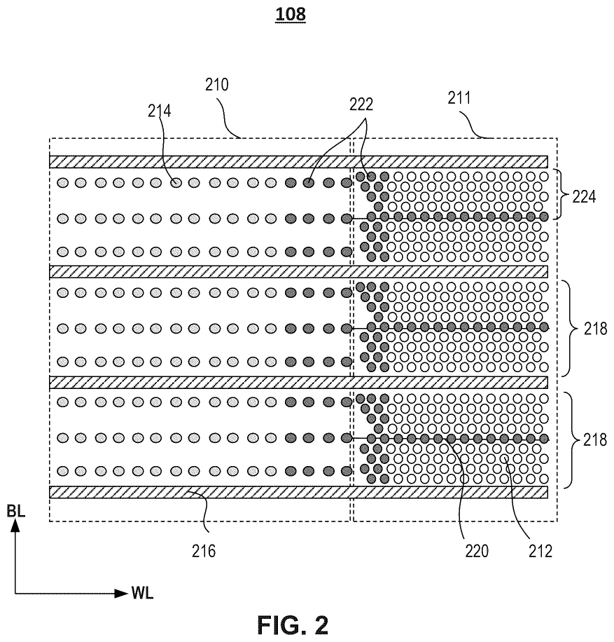

Referring to FIG. 2, an enlarged top-down view of a region 108 in FIG. 1 is illustrated, according to some embodiments of the present disclosure. The region 108 of the 3D memory device 100 can include a staircase region 210 and a channel structure region 211. The channel structure region 211 can include an array of memory strings 212, each including a plurality of stacked memory cells. The staircase region 210 can include a staircase structure and an array of contact structures 214 formed on the staircase structure. In some embodiments, a plurality of slit structures 216, extending in WL direction across the channel structure region 211 and the staircase region 210, can divide a memory block into multiple sub-storage units, for example, multiple memory fingers 218. At least some slit structures 216 can function as the common source contact (e.g., array common source or ACS) for an array of memory strings 212 in channel structure regions 211. A top select gate cut 220 can be disposed, for example, in the middle of each memory finger 218 to divide a top select gate (TSG) of the memory finger 218 into two portions, and thereby can divide a memory finger into two memory slices 224, where memory cells in a memory slice 224 that share the same word line form a programmable (read/write) memory page. While erase operation of a 3D NAND memory can be carried out at memory block level, read and write operations can be carried out at memory page level. A memory page can be kilobytes (KB) in size. In some embodiments, region 108 also includes dummy memory strings 222 for process variation control during fabrication and/or for additional mechanical support.

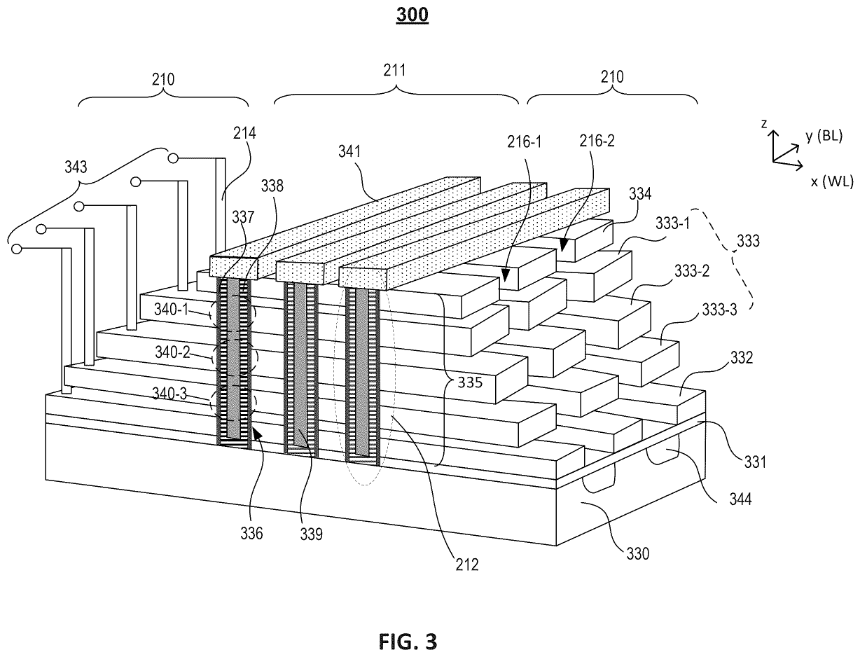

FIG. 3 illustrates a perspective view of a portion of an exemplary three-dimensional (3D) memory array structure 300, according to some embodiments of the present disclosure. The memory array structure 300 includes a substrate 330, an insulating film 331 over the substrate 330, a tier of lower select gates (LSGs) 332 over the insulating film 331, and a plurality of tiers of control gates 333, also referred to as “word lines (WLs),” stacking on top of the LSGs 332 to form a film stack 335 of alternating conductive and dielectric layers. The dielectric layers adjacent to the tiers of control gates are not shown in FIG. 3 for clarity.

The control gates of each tier are separated by slit structures 216-1 and 216-2 through the film stack 335. The memory array structure 300 also includes a tier of top select gates (TSGs) 334 over the stack of control gates 333. The stack of TSG 334, control gates 333 and LSG 332 is also referred to as “gate electrodes”. The memory array structure 300 further includes memory strings 212 and doped source line regions 344 in portions of substrate 330 between adjacent LSGs 332. Each memory strings 212 includes a channel hole 336 extending through the insulating film 331 and the film stack 335 of alternating conductive and dielectric layers. Memory strings 212 also includes a memory film 337 on a sidewall of the channel hole 336, a channel layer 338 over the memory film 337, and a core filling film 339 surrounded by the channel layer 338. A memory cell 340 (e.g., 340-1, 340-2, 340-3) can be formed at the intersection of the control gate 333 (e.g., 333-1, 333-2, 333-3) and the memory string 212. A portion of the channel layer 338 responds to the respective control gate is also referred to as the channel layer 338 of the memory cell. The memory array structure 300 further includes a plurality of bit lines (BLs) 341 connected with the memory strings 212 over the TSGs 334. The memory array structure 300 also includes a plurality of metal interconnect lines 343 connected with the gate electrodes through a plurality of contact structures 214. The edge of the film stack 335 is configured in a shape of staircase to allow an electrical connection to each tier of the gate electrodes.

In FIG. 3, for illustrative purposes, three tiers of control gates 333-1, 333-2, and 333-3 are shown together with one tier of TSG 334 and one tier of LSG 332. In this example, each memory string 212 can include three memory cells 340-1, 340-2 and 340-3, corresponding to the control gates 333-1, 333-2 and 333-3, respectively. In some embodiments, the number of control gates and the number of memory cells can be more than three to increase storage capacity. The memory array structure 300 can also include other structures, for example, TSG cut, common source contact (i.e., array common source) and dummy memory string. These structures are not shown in FIG. 3 for simplicity.

Traditionally, the top select gate (TSG) is formed at the same time as word lines (or control gates) for the memory cells, which includes a memory film of charge trapping. When a voltage is applied to the top select gate, the threshold voltage Vₜₕ of the top select transistor drifts, just like the threshold voltages Vₜₕ of the memory cells. The change of the threshold voltage causes uncertainty of the switching property in the top select transistor, and thereby affecting the performance of the 3D NAND memory. Therefore, a need exists to provide a method for forming a 3D NAND memory with improved top select transistors

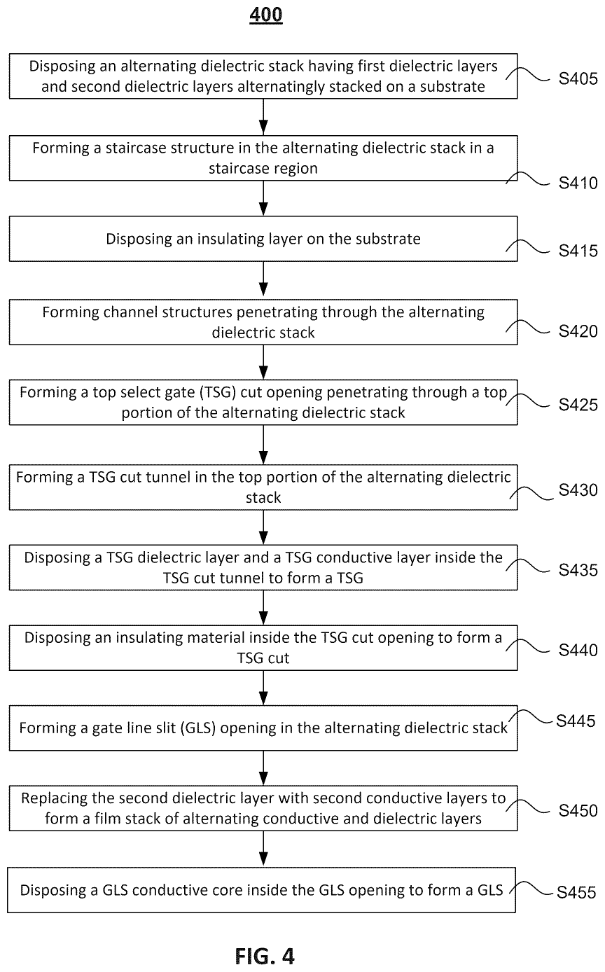

FIG. 4 illustrates a method 400 for forming a three-dimensional (3D) memory device, according to some embodiments of the present disclosure. It should be understood that process steps shown in method 400 are not exhaustive and that other steps can be performed as well before, after, or between any of the illustrated steps. In some embodiments, some process steps of method 400 can be omitted, or other process steps can also be included, which are not described here for simplicity. In some embodiments, process steps of method 400 can be performed in a different order and/or vary.

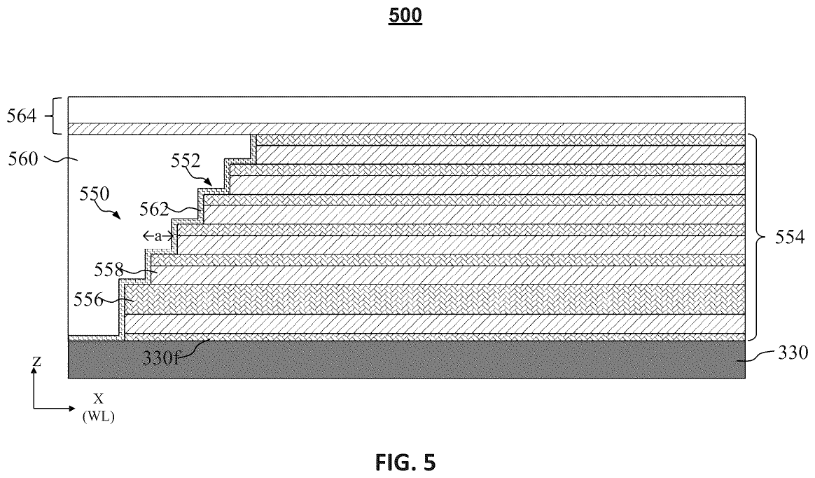

FIGS. 5-12 illustrate exemplary structures of the 3D memory device at certain process step according to the method 400.

Referring to FIG. 4, at process step S405, an alternating dielectric stack can be disposed on a substrate. At process step S410, a staircase structure can be formed in the alternating dielectric stack. At process step S415, an insulating layer can be disposed over the substrate, covering the staircase structure and the alternating dielectric stack. A cross-sectional view of an exemplary 3D memory structure 500 is shown in FIG. 5A, according to the process steps S405-S415.

As shown in FIG. 5, the 3D memory structure 500 includes an alternating dielectric stack 554 having first dielectric layers 556 and second dielectric layers 558 alternatingly stacked on the substrate 330.

The substrate 330 can provide a platform for forming subsequent structures. In some embodiments, the substrate 330 can be any suitable semiconductor substrate having any suitable semiconductor materials, such as monocrystalline, polycrystalline or single crystalline semiconductors. For example, the substrate 330 can include silicon, silicon germanium (SiGe), germanium (Ge), gallium arsenide (GaAs), gallium nitride, silicon carbide, III-V compound, II-VI compound, or any combinations thereof. In some embodiments, the substrate 330 can have a composite structure and include a semiconductor layer formed on a handle wafer. For example, the substrate 330 can be silicon-on-insulator (SOI), germanium-on-insulator (GOI), or silicon germanium-on-insulator (SGOI).

A front surface 330f of the substrate 330 is also referred to as a “main surface” or a “top surface” of the substrate herein. Layers of materials can be disposed on the front surface 330f of the substrate 330. A “topmost” or “upper” layer is a layer farthest or farther away from the front surface 330f of the substrate. A “bottommost” or “lower” layer is a layer closest or closer to the front surface 330f of the substrate.

In some embodiments, the alternating dielectric stack 554 includes a plurality of dielectric layer pairs alternatingly stacked along a vertical direction (i.e., z-direction) perpendicular to the front surface 330f of the substrate 330, where each dielectric layer pair includes the first dielectric layer 556 (also referred to as “dielectric layer”) and the second dielectric layer 558 (also referred to as “sacrificial layer”) that is different from the first dielectric layer 556. The alternating dielectric stack 554 extends in a lateral direction that is parallel to the front surface 330f of the substrate 330.

In the alternating dielectric stack 554, first dielectric layers 556 and second dielectric layers 558 alternate in a vertical direction, perpendicular to the substrate 330. In the other words, each second dielectric layer 558 can be sandwiched between two first dielectric layers 556, and each first dielectric layer 556 can be sandwiched between two second dielectric layers 558 (except the bottommost and the topmost layer).

The formation of the alternating dielectric stack 554 can include disposing the first dielectric layers 556 to each have the same thickness or to have different thicknesses. Example thicknesses of the first dielectric layers 556 can range from 10 nm to 500 nm, preferably about 25 nm. Similarly, the second dielectric layer 558 can each have the same thickness or have different thicknesses. Example thicknesses of the second dielectric layer 558 can range from 10 nm to 500 nm, preferably about 35 nm. It should be understood that the number of dielectric layer pairs in FIG. 5 is for illustrative purposes only and that any suitable number of layers may be included in the alternating dielectric stack 554.

In some embodiments, the first dielectric layer 556 includes any suitable insulating materials, for example, silicon oxide, silicon oxynitride, silicon nitride, TEOS or silicon oxide with F-, C-, N-, and/or H-incorporation. The first dielectric layer 556 can also include high-k dielectric materials, for example, hafnium oxide, zirconium oxide, aluminum oxide, tantalum oxide, or lanthanum oxide films. In some embodiments, the first dielectric layer 556 can be any combination of the above materials.

The formation of the first dielectric layer 556 can include any suitable deposition methods such as, chemical vapor deposition (CVD), physical vapor deposition (PVD), plasma-enhanced CVD (PECVD), rapid thermal chemical vapor deposition (RTCVD), low pressure chemical vapor deposition (LPCVD), sputtering, metal-organic chemical vapor deposition (MOCVD), atomic layer deposition (ALD), high-density-plasma CVD (HDP-CVD), sputtering, evaporation, thermal oxidation, nitridation, any other suitable deposition method, and/or combinations thereof.

In some embodiments, the second dielectric layer 558 includes any suitable material that is different from the first dielectric layer 556 and can be removed selectively with respect to the first dielectric layer 556. For example, the second dielectric layer 558 can include silicon oxide, silicon oxynitride, silicon nitride, TEOS, poly-crystalline silicon, poly-crystalline germanium, poly-crystalline germanium-silicon, and any combinations thereof. In some embodiments, the second dielectric layer 558 also includes amorphous semiconductor materials, such as amorphous silicon or amorphous germanium. The second dielectric layer 558 can be disposed using a similar technique as the first dielectric layer 556, such as CVD, PVD, ALD, sputtering, evaporation, thermal oxidation or nitridation, or any combination thereof.

In some embodiments, the first dielectric layer 556 can be silicon oxide and the second dielectric layer 558 can be silicon nitride.

In some embodiments, the alternating dielectric stack 554 can include layers in addition to the first dielectric layer 556 and the second dielectric layer 558, and can be made of different materials and/or with different thicknesses.

As shown in FIG. 5, the 3D memory structure 500 also includes a staircase structure 550 with a plurality of staircase steps 552 formed in the alternating dielectric stack 554 in the staircase region. The staircase step 552, or a “staircase layer”, refers to a layer stack with the same lateral dimension in a surface parallel to the substrate surface 330f. Each of the staircase steps 552 terminates at a shorter length than the staircase step underneath, with a lateral dimension “a” shown in FIG. 5.

In some embodiments, each of the staircase steps 552 includes one pair of the first dielectric layer 556 and the second dielectric layer 558. In some embodiments, each of the staircase steps 552 can include two or more pairs of the first dielectric layer 556 and the second dielectric layer 558. As shown in FIG. 5, each of the staircase steps 552 includes one pair of the first dielectric layer 556 and the second dielectric layer 558. In some embodiments, the second dielectric layer 558 is on top of the first dielectric layer 556 in each staircase step 552. Each of the staircase steps 552 exposes a portion of the second dielectric layer 558 at the end of alternating dielectric stack 554. In some embodiments, the first dielectric layer 556 is on top of the second dielectric layer 558 in each staircase step 552.

The staircase structure 550 can be formed by applying a repetitive etch-trim process on the alternating dielectric stack 554. The etch-trim process includes an etching process and a trimming process. During the etching process, a portion of the staircase step 552 with exposed surface can be removed. The remaining portion of the staircase step 552, either covered by upper levels of staircase steps or covered by a patterning mask, is not etched. The etch depth is a thickness of the staircase step 552. In some embodiments, the thickness of the staircase step 552 is a thickness of one pair of the first dielectric layer 556 and the second dielectric layer 558. The etching process for the first dielectric layer 556 can have a high selectivity over the second dielectric layer 558, and/or vice versa. Accordingly, an underlying dielectric layer pair can function as an etch-stop layer. By switching etching process for each layer, the staircase step 552 can be etched during one etching cycle. And as a result, one of the staircase steps 552 can be formed during each etch-trim cycle.

In some embodiments, the staircase step 552 can be etched using an anisotropic etching such as a reactive ion etch (RIE) or other dry etch processes. In some embodiments, the first dielectric layer 556 is silicon oxide. In this example, the etching of silicon oxide can include RIE using fluorine based gases, for example, carbon-fluorine (CF₄), hexafluoroethane (C₂F₆), CHF₃, or C₃F₆ and/or any other suitable gases. In some embodiments, the silicon oxide layer can be removed by wet chemistry, such as hydrofluoric acid or a mixture of hydrofluoric acid and ethylene glycol. In some embodiments, a timed etching approach can be used. In some embodiments, the second dielectric layer 558 is silicon nitride. In this example, the etching of silicon nitride can include RIE using O₂, N₂, CF₄, NF₃, Cl₂, HBr, BCl₃, and/or combinations thereof. The methods and etchants to remove a single layer stack should not be limited by the embodiments of the present disclosure.

The trimming process includes applying a suitable etching process (e.g., an isotropic dry etch or a wet etch) on the patterning mask such that the patterning mask can be pulled back laterally. The lateral pull-back dimension determines the lateral dimension “a” of each step of the staircase structure 550. After trimming the patterning mask, one portion of a topmost staircase step 552 is exposed and the other potion of the topmost staircase step 552 remains covered by the patterning mask. The next cycle of etch-trim process resumes with the etching process. In some embodiments, the patterning mask trimming process can include dry etching, such as RIE using O₂, Ar, N₂, etc. It is noted that the number of staircase structures and the number of dielectric layer pairs in the 3D memory structure 500 are not limited to the examples herein.

As shown in FIG. 5, the 3D memory structure 500 also includes an insulating layer 560 disposed over the substrate, covering the staircase structure 550 and the alternating dielectric stack 554. The insulating layer 560 can include any suitable insulating material, for example, silicon oxide, silicon oxynitride, silicon nitride, TEOS, spin-on-glass, low-k dielectric material, such as carbon-doped oxide (CDO or SiOC or SiOC:H), or fluorine doped oxide (SiOF), etc. The insulating layer 560 can be disposed by CVD, PVD, ALD, sputtering, evaporating, etc. In some embodiments, the insulating layer 560 can have a planar top surface over the staircase structure 550 and the alternating dielectric stack 554. The insulating layer 560 can be planarized using CMP and/or RIE etch-back.

At completion of the process step S415, the staircase structure 550 is formed in the staircase region, which can be used to form electrical contacts to word lines in subsequent processes.

In some embodiments, a barrier layer 562 (also referred to as the staircase protection layer) can be disposed on the staircase structure and the alternating dielectric stack, prior to disposing the insulating layer 560. The barrier layer 562 can cover the staircase structure 550 and the alternating dielectric stack 554 on both lateral surfaces and vertical sidewalls. The barrier layer 562 on lateral surfaces and vertical sidewalls can have the same or different thicknesses. The barrier layer 562 can include a thickness in a range between 10 nm to 100 nm.

In some embodiments, the barrier layer 562 can be any suitable insulating material, for example, silicon oxide, silicon nitride, silicon oxynitrde, TEOS, high-k dielectric material (Al₂O₃, HfO₂, Ta₂O₃, ZrO₂, La₂O₃, etc.), or any combination thereof. The barrier layer 562 can be disposed by any suitable thin film deposition techniques such as CVD (e.g., PECVD, LPCVD, RTCVD, HDP-CVD, MOCVD, etc.), ALD, PVD, sputtering, evaporation, etc. In some embodiments, the barrier layer 562 can function as an etch-stop for forming contact structures on the staircase steps in the subsequent processes. In this example, the barrier layer 562 can include any suitable insulating material that is different from the second dielectric layer 558. In some embodiments, the first barrier layer 562 can be silicon oxide.

In some embodiments, the 3D memory structure 500 also includes a top dielectric stack 564 disposed on the insulating layer 560 and the alternating dielectric stack 554. The top dielectric stack 564 can include any suitable dielectric material, for example silicon oxide, silicon nitride, silicon oxynitrde, TEOS, high-k dielectric material (Al₂O₃, HfO₂, Ta₂O₃, ZrO₂, La₂O₃, etc.), or any combination thereof.

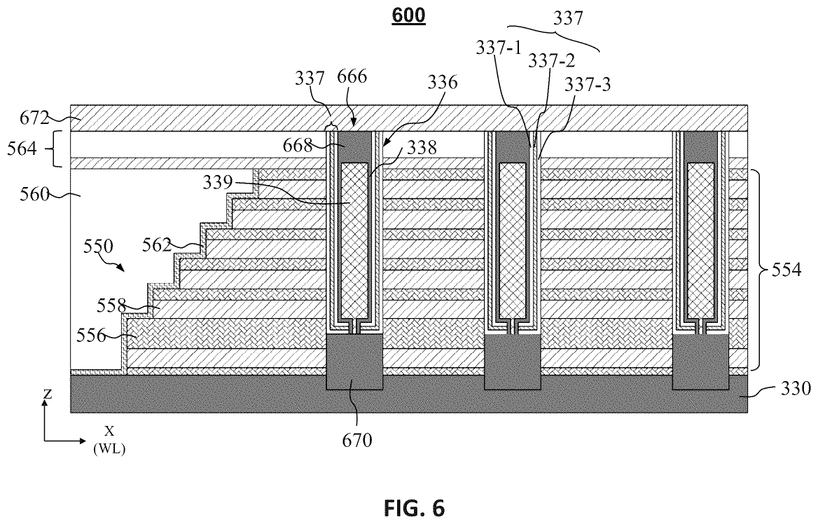

Referring to FIG. 4, at process step S420, a plurality of channel structures can be formed in the channel structure region, where each channel structure penetrates through the alternating dielectric stack. A cross-sectional view of an exemplary 3D memory structure 600 is shown in FIG. 6, according to the process step S420.

As shown in FIG. 6, the 3D memory structure 600 includes the plurality of channel holes 336 penetrating vertically through the alternating dielectric stack 554. Techniques used to form the channel holes 336 can include processes such as photolithography and etching. The etching process to form the channel holes 336 can also include a dry etching, a wet etching, or a combination thereof. In some embodiments, the alternating dielectric stack 554 can be etched using an anisotropic etching such as a reactive ion etch (RIE). In some embodiments, fluorine or chlorine based gases such as carbon-fluorine (CF₄), hexafluoroethane (C₂F₆), CHF₃, C₃F₆, Cl₂, BCl₃, etc., or any combination thereof, can be used. The methods and etchants to etch the first dielectric layer 556 and the second dielectric layers 558 should not be limited by the embodiments of the present disclosure.

After forming the channel holes 336, the memory film 337 can be disposed sidewalls of the channel holes 336. In some embodiments, the memory film 337 can be a composite layer including a tunneling layer 337-1, a storage layer 337-2 (also known as “charge trapping layer”), and a blocking layer 337-3. In some embodiments, the tunneling layer 337-1, the storage layer 337-2, and the blocking layer 337-3 are arranged along a direction from a center of the channel hole 336 toward the outer of the channel hole 336 in the above order. The tunneling layer 337-1 can include silicon oxide, silicon nitride, or any combination thereof. The blocking layer 337-3 can include silicon oxide, silicon nitride, high dielectric constant (high-k) dielectrics, or any combination thereof. The storage layer 337-2 can include silicon nitride, silicon oxynitride, silicon, or any combination thereof. In some embodiments, the memory film 337 includes ONO dielectrics (e.g., the tunneling layer including silicon oxide, the storage layer including silicon nitride, and the blocking layer including silicon oxide). The memory film 337 can be formed by using a thin film deposition process, such as ALD, CVD, PVD, sputtering or any other suitable process. In some embodiments, a thickness of the memory film 337 can be in a range from about 10 nm to about 50 nm.

Next, the channel layer 338 and the core filling film 339 can be disposed in the channel holes 336, where the channel layer 338 covers a sidewall of the memory film 337 inside the channel hole 336. The channel layer 338 can be any suitable semiconductor material such as silicon. In some embodiments, the channel layer 338 can be amorphous, polysilicon, or single crystalline silicon. The channel layer 338 can be formed by any suitable thin film deposition processes including, but not limited to, CVD, PVD, ALD, sputtering, evaporation, or a combination thereof. In some embodiments, a thickness of the channel layer 338 can be in a range from about 10 nm to about 30 nm.

In some embodiments, the core filling film 339 can be disposed to fill the channel holes 336 to form a channel structure 666. In some embodiments, the middle of the core filling film 339 can include one or more seams 860. The core filling film 339 can be any suitable insulator, for example, silicon oxide, silicon nitride, silicon oxynitride, spin-on-glass, boron or phosphorus doped silicon oxide, carbon-doped oxide (CDO or SiOC or SiOC:H), fluorine doped oxide (SiOF), or any combination thereof. The core filling film 339 can be deposited by using, for example, ALD, PVD, CVD, spin-coating, sputtering, or any other suitable film deposition techniques. The core filling film 339 can also be formed by using repeated deposition and etch-back processes. The etch-back process can include, but not limited to, a wet etching, a dry etching, or a combination thereof. In some embodiments, one or more seams can be formed in the core filling film 339 to reduce mechanical stress.

In some embodiments, the 3D memory structure 600 also includes a channel top plug 668 at a top portion of the channel structure 666. The channel top plug 668 can form electrical contact with the channel layer 338 inside the channel hole 336. The channel top plug 668 can be amorphous or polycrystalline silicon, and can include metal, metal alloy and/or metal silicide, for example, tungsten, titanium, tantalum, tungsten nitride, titanium nitride, tantalum nitride, nickel silicide, cobalt silicide, tungsten silicide, titanium silicide, or a combination thereof. The channel top plug 668 can be formed by a recess etching process followed by thin film deposition. The recess etching process includes wet etch, dry etch or a combination thereof. The thin film deposition includes CVD, PVD, ALD, sputtering, or any other suitable processes. The channel top plug 668 can function as a drain side contact for the channel structure.

In some embodiments, the 3D memory device 600 can also include an epitaxial plug 670 at bottom of the channel structure 666. The epitaxial plug 670 can include any suitable semiconductor material, such as silicon, silicon germanium, germanium, gallium arsenide, gallium nitride, III-V compound, or any combination thereof. The epitaxial plug 670 can be epitaxially grown from the substrate 330. In some embodiments, the epitaxial plug 670 can also include a polycrystalline semiconductor material, for example, polycrystalline silicon. In some embodiments, a portion of the memory film 337 at the bottom of the channel hole 336 can be removed such that the channel layer 338 can directly contact with the epitaxial plug 670. The epitaxial plug 670 extends through at least one of the second dielectric layers 558 in a bottom portion of the alternating dielectric stack 554, where a lower select transistor controlled by the LSG 332 (see FIG. 3) can be formed in the subsequent processes. In some embodiments, the epitaxial plug 670 extends through a bottommost second dielectric layer.

It is noted that the number and arrangement of the channel structure 666 in the channel structure region can be designed according to actual storage requirements, and are not limited to the example shown in FIG. 6. As discussed previously with respect to FIG. 2, the channel structure region 211 provides the storage function for the three-dimensional memory.

In some embodiment, the 3D memory structure 600 also includes a plurality of dummy channel holes (not shown in FIG. 6) in the staircase region. The dummy channel holes (DCHs) penetrate through a portion of the staircase structure 550 (i.e., a portion of the alternating dielectric stack 554) and extend into the substrate 330. After forming the DCHs, any suitable insulator can be disposed inside the DCHs to form dummy channel structures. The dummy channel structures formed in the staircase region (see, e.g., FIG. 2) can be configured to provide mechanical support for the 3D memory structures in the subsequent processes.

In some embodiments, the channel structures 666 can be planarized to have coplanar surfaces with the top dielectric stack 564. The planarization process includes RIE etch back, CMP or a combination thereof.

The 3D memory structure 600 can also include a capping layer 672, disposed on the top dielectric stack 564 to cover the channel structures 666. The capping layer 672 can include silicon oxide, silicon nitride, silicon oxynitride, TEOS, or a combination thereof. The capping layer 672 can be deposited by CVD, PVD, ALD, sputtering, etc.

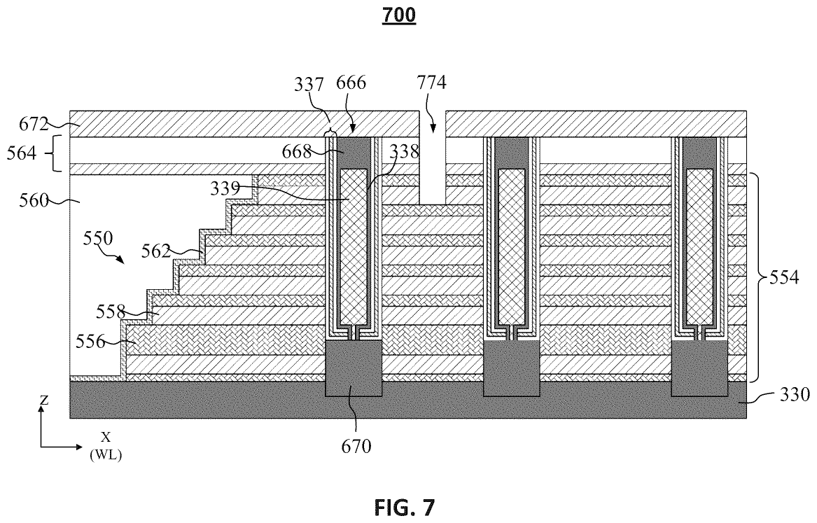

Referring to FIG. 4, at process step S425, a top select gate (TSG) cut opening can be formed in a top portion of the alternating dielectric stack. A cross-sectional view of an exemplary 3D memory structure 700 is shown in FIG. 7, according to the process step S425.

As shown in FIG. 7, the 3D memory structure 700 includes a TSG cut opening 774, penetrating through a top portion of the alternating dielectric stack 554. The TSG cut opening 774 extends into at least one of the second dielectric layer 558 in the top portion of the alternating dielectric stack 554, where a top select transistor controlled by the TSG 334 (see FIG. 3) can be formed in the subsequent processes. Shown in FIG. 7, the TSG cut opening 774 extends into a topmost second dielectric layer. In some embodiments, the TSG cut opening 774 also penetrates through the capping layer 672 and the top dielectric stack 564.

The TSG cut opening 774 can be formed by a lithography process and an etching process. The etching process can include any suitable dry etching, wet etching and/or a combination thereof.

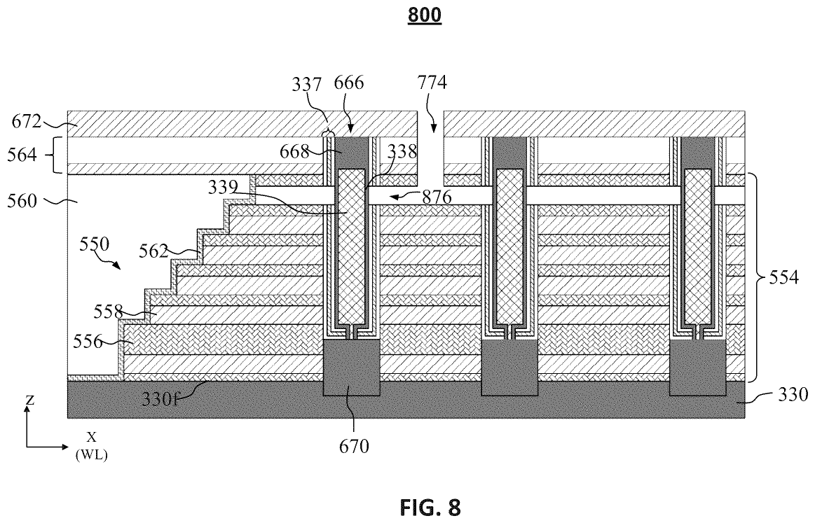

Referring to FIG. 4, at process step S430, a TSG cut tunnel can be formed in the top portion of the alternating dielectric stack. A cross-sectional view of an exemplary 3D memory structure 800 is shown in FIG. 8, according to the process step S430.

As shown in FIG. 8, the 3D memory structure 800 includes a TSG cut tunnel 876 in the top portion of the alternating dielectric stack 554. The TSG cut tunnel 876 can be formed by removing the second dielectric layer 558 in the top portion of the alternating dielectric stack 554 through the TSG cut opening 774. In some embodiments, the topmost second dielectric layer 558 of the alternating dielectric stack 554 can be removed to form the TSG cut tunnel 876. The TSG cut tunnel 876 can extend in a lateral direction between adjacent first dielectric layers 556. It is noted that, the term “lateral/laterally” used herein means the plane parallel to the top surface 330f of the substrate 330. The second dielectric layers 558 in the alternating dielectric stack 554 are also referred to as sacrificial layers, and can be removed selectively from between the first dielectric layers 556. In the other words, the etching process of the second dielectric layers 558 can have minimal impact on the first dielectric layers 556. The second dielectric layers 558 can be removed by an isotropic dry etch and/or wet etch. The plasma and/or chemical used in the dry/wet etch can travel vertically and laterally from the TSG cut opening 774. In some embodiments, the second dielectric layer 558 can be silicon nitride, and the first dielectric layer 556 can be silicon oxide. In this example, the second dielectric layer 558 can be removed by RIE using one or more etchants of CF₄, CHF₃, C₄F₈, C₄F₆, and CH₂F₂, etc. In some embodiments, the second dielectric layer 558 can be removed using wet etch, such as phosphoric acid.

After removing the second dielectric layers 558, a portion of the memory film 337 can be exposed in the TSG cut tunnel 876. The exposed portion of the memory film 337 inside the TSG cut tunnel 876 can then be removed also. The etching process for the exposed portion of the memory film 337 can include any suitable dry/wet etching. In some embodiments, a portion of the exposed portion of the memory film 337 inside the TSG cut tunnel 876 can be removed. For example, a portion of the blocking layer 337-3 and the storage layer 337-2 of the memory film 337 can be removed and at least a portion of the tunneling layer 337-1 can remain.

After completing the operation step S430, a portion of the channel layer 338 can be exposed inside the TSG cut tunnel 876.

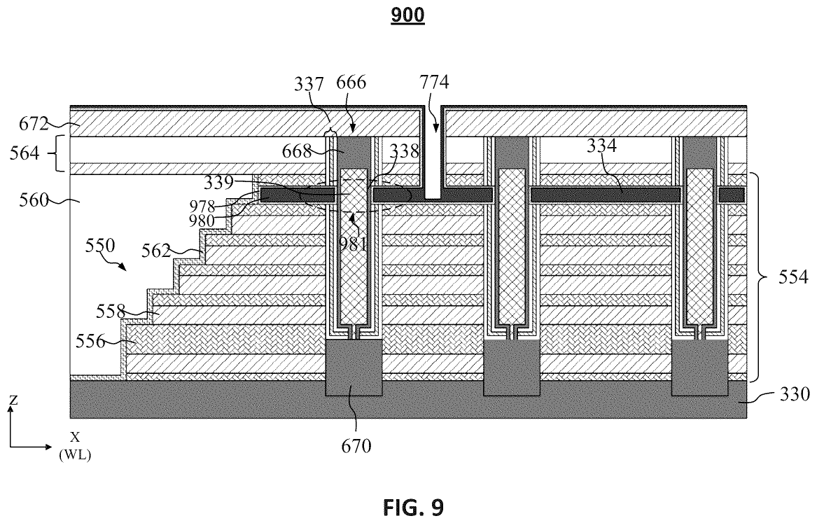

Referring to FIG. 4, at process step S435, a TSG dielectric layer and a TSG conductive layer can be disposed inside the TSG cut tunnel. A cross-sectional view of an exemplary 3D memory structure 900 is shown in FIG. 9, according to the process step S435.

As shown in FIG. 9, the 3D memory structure 900 includes a TSG dielectric layer 978 and a TSG conductive layer 980 (also referred to a first conductive layer) disposed inside the TSG cut tunnel 876 (in FIG. 8).

After removing the second dielectric layer 558 and at least the exposed charge trapping layer 337-2 of the memory film 337 inside the TSG cut tunnel 876 as shown previously at operation step S430, the TSG dielectric layer 978 can be disposed inside the TSG cut tunnel 876 to cover the exposed channel layer 338 through the TSG cut opening 774. The TSG dielectric layer 978 can include any suitable insulator that is different from the second dielectric layer 558 such that the TSG dielectric layer 978 will not be removed together with the second dielectric layer 558 in the subsequent processes. In some embodiments, the TSG dielectric layer 978 can also be a composite layer, where the key difference between the TSG dielectric layer 978 and the memory film 337 is that the TSG dielectric layer 978 does not include the storage layer or the charge trapping layer. In some embodiments, the TSG dielectric layer 978 can include, for example, silicon oxide, silicon oxynitride, and/or a combination thereof. In some embodiments, the TSG dielectric layer 978 can include oxygen-rich silicon oxynitride, in which oxygen content is higher than nitrogen content. The TSG dielectric layer 978 can also include high-k dielectric materials, such as hafnium oxide, zirconium oxide, aluminum oxide, tantalum oxide, lanthanum oxide, and/or any combination thereof. In some embodiments, the TSG dielectric layer 978 includes a dielectric material with a defective or charge trap density less than, for example, 1012 cm2. The TSG dielectric layer 978 can be disposed by one or more suitable deposition processes, such as CVD, PVD, and/or ALD. In some embodiments, the TSG dielectric layer 978 is silicon oxide deposited by ALD.

Next, the TSG conductive layer 980 can be disposed inside the TSG cut tunnel 876 through the TSG cut opening 774. The TSG conductive layer 980 can be disposed on the TSG dielectric layer 978 to form the TSG 334 (as seen in FIG. 3) in the top portion of the alternating dielectric stack 554.

The TSG conductive layer 980 can be formed by filling the TSG cut tunnel 876 with a suitable conductive material. The conductive material for the TSG conductive layer 980 can include poly-crystalline semiconductors, such as poly-crystalline silicon, poly-crystalline germanium, poly-crystalline germanium-silicon and any other suitable material, and/or combinations thereof. In some embodiments, the poly-crystalline material can be incorporated (i.e., doped) with any suitable n-type or p-type of dopants, such as boron, phosphorous, arsenic, or any combination thereof. In some embodiments, the TSG conductive layer 980 can also be amorphous semiconductors such as amorphous silicon. The polycrystalline or amorphous silicon can facilitate easier etching process that goes through the TSG conductive layer 980, for example, the subsequent process for forming the GLS opening 1182.

In some embodiments, the TSG conductive layer 980 can also include metal or metal alloys such as tungsten (W), aluminum (Al), titanium (Ti), copper (Cu), cobalt (Co), nickel (Ni), titanium nitride (TiN), tungsten nitride (WN), tantalum (Ta), tantalum nitride (TaN), AlTi, or any combination thereof. The TSG conductive layer 980 can be disposed using a suitable deposition method such as chemical vapor deposition (CVD) (e.g., LPCVD, PECVD, MOCVD, RTCVD, etc.), physical vapor deposition (PVD), sputtering, evaporation, atomic layer deposition (ALD), or any combination thereof. In some embodiments, TSG conductive layer 980 include polycrystalline silicon, in-situ doped with n-type dopants (e.g., phosphorus or arsenic).

In the example that the exposed portion of the blocking layer 337-3 and the storage layer 337-2 of the memory film 337 is removed inside the TSG cut tunnel 876, at least a portion of the tunneling layer 337-1 can serve as the TSG dielectric layer 978. In some embodiments, additional dielectric material can be deposited inside the TSG cut tunnel 876 such that the TSG dielectric layer 978 includes at least portion of the tunneling layer 337-1.

In some embodiments, after forming the TSG 334, the TSG conductive layer 980 disposed on a sidewall and a bottom of the TSG cut opening 774 can be removed by a dry or wet etching process such that adjacent TSGs 334 can be electrically isolated by the TSG cut opening 774. In some embodiments, the TSG conductive layer 980 disposed on top of the capping layer 672 can also be removed by a dry or wet etching process.

At the completion of the process step S435, a top select transistor 981 can be formed at the intersection of the TSG conductive layer 980, the TSG dielectric layer 978 and the channel layer 338. The top select transistor 981 can function as a MOSFET, where a voltage applied on the gate (i.e., the TSG conductive layer 980) can switch on or off the channel (i.e., a corresponding portion of the channel layer 338). The gate dielectric of the top select transistor 981 is the TSG dielectric layer 978, where the TSG dielectric layer 978 contacts the TSG conductive layer 980 and the exposed portion of the channel layer 338. To minimize the changes of the threshold voltage of the top select transistor 981, the TSG dielectric layer 978 includes a dielectric material that has minimum charge traps. To achieve better switching property, the TSG dielectric layer 978 can have a thickness thinner than the memory film 337 in a lateral direction parallel to the substrate. In the other words, a thickness of the TSG dielectric layer 978 in between the TSG conductive layer 980 and the channel layer 338 can be in a range between 10 nm to 30 nm. In some embodiments, to reduce leakage current, the TSG dielectric layer 978 can be thicker than the memory film 337.

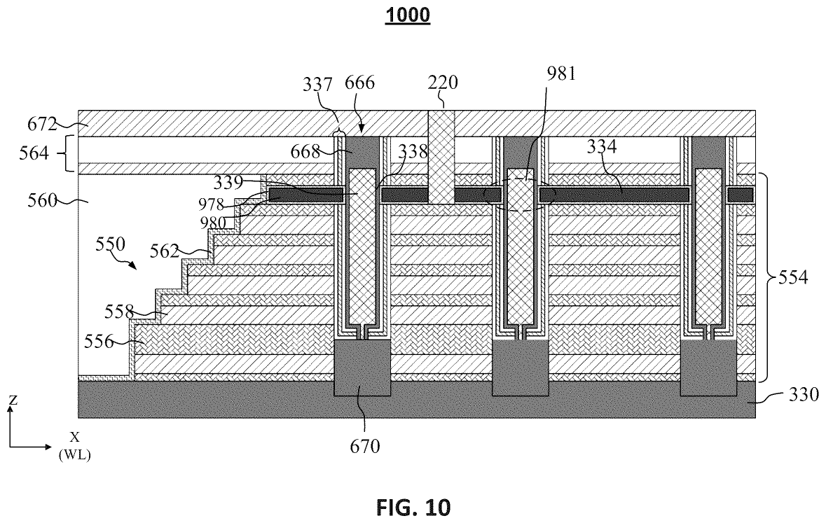

Referring to FIG. 4, at process step S440, an insulating material can be disposed inside the TSG cut opening to form a TSG cut. A cross-sectional view of an exemplary 3D memory structure 1000 is shown in FIG. 10, according to the process step S440.

As shown in FIG. 10, the 3D memory structure 1000 includes the TSG cut 220 (similar to the TSG cut 220 in FIG. 2). The TSG cut 220 penetrates through the TSG conductive layer 980 to separate the TSGs 334. The TSG cut 220 can include any suitable insulating material disposed inside the TSG cut opening 774 (in FIG. 9) after removing the TSG conductive layer 980 from the sidewall and the bottom of the TSG cut opening 774. The insulating material of the TSG cut 220 can include silicon oxide, silicon nitride, silicon oxynitride, boron or phosphorus doped silicon oxide, carbon-doped oxide (CDO or SiOC or SiOC:H), or fluorine doped oxide (SiOF), or any combination thereof. The insulating material for the TSG cut 220 can be deposited by using, for example, ALD, CVD (e.g., PECVD, RTCVD, LPCVD, etc.), PVD, sputtering, evaporating, or any other suitable film deposition techniques.

In some embodiments, the insulating material of the TSG cut 220 disposed outside the TSG cut opening 774 (e.g., on top of the capping layer 672) can be removed by dry/wet etching (e.g., RIE) and/or CMP. Any residual TSG conductive layer 980 and/or TSG dielectric layer 978 on top of the capping layer 672 can also be removed. As such, a top surface of the TSG cut 220 can be coplanar with a top surface of the capping layer 672.

As discussed previously, the TSG cut 220 can divide the TSG conductive layer 980 to form separate TSGs 334. Each TSG 334 can be independently controlled. In some embodiments, the top select transistor 981 (e.g., metal-oxide-semiconductor field-effect-transistor or “MOSFET”) can be formed at an intersection between the TSG 334, the TSG dielectric layer 978 and the channel layer 338 of the channel structure 666. The top select transistor 981 can be switched on or off to control the connectivity between the channel layer 338 below (e.g., memory cells formed in the subsequent processes) and the channel top plug 668 (and the bit line formed in the subsequent processes). The top select transistor 981 formed by the method 400 does not have a charge trapping layer (or storage layer). The TSG dielectric layer 978 functions as a gate dielectric for the top select transistor, which can include a dielectric having minimum number of defects or charge traps. In some embodiments, the TSG dielectric layer 978 can have a number of charge traps or defects less than the charge trapping layer 337-2 in the memory film 337, for example, a density less than 1012 cm2. When a voltage is applied on the TSG 334 to switch on or off the top select transistor 981, shift of a threshold voltage of the top select transistor 981 due to charge trapping can be reduced or eliminated. By removing the charge trapping layer 337-2 and forming a MOSFET structure with the TSG dielectric layer 978, the top select transistor can be switched on and off with a higher speed and less hysteresis, where shifts of the threshold voltage of the top select transistor can be minimized. Charge transfer during cycles of programming and erasing can also be minimized in the top select transistor 981. Accordingly, reliability of the top select transistor 981 can thus be improved. Because only a few process steps are changed, the method 400 can be compatible with other processes in the fabrication of the three-dimensional memory.

As shown in FIG. 2, the TSG cut 220 extends lateral along the WL direction and can divide a memory block into a plurality of sub-storage units (e.g., memory fingers 218). In some embodiments, the TSG cut 220 can further divide the memory finger 218 into multiple memory slices 224. The TSG cut 220 electrically isolates the TSGs 334 such that each TSG 334 and corresponding top select transistor can be independently controlled. As such, each memory slice 224 can be controlled independently from each other, which can effectively reduce the programming, reading and erasing time as well as data transmission time. Efficiency of data storage can be improved.

At the completion of the process step S440, the alternating dielectric stack 554 includes two sub-stacks. A top stack includes the TSG conductive layer 980 and the first dielectric layer 556, and a bottom stack includes the first dielectric layers 556 and the second dielectric layers 558.

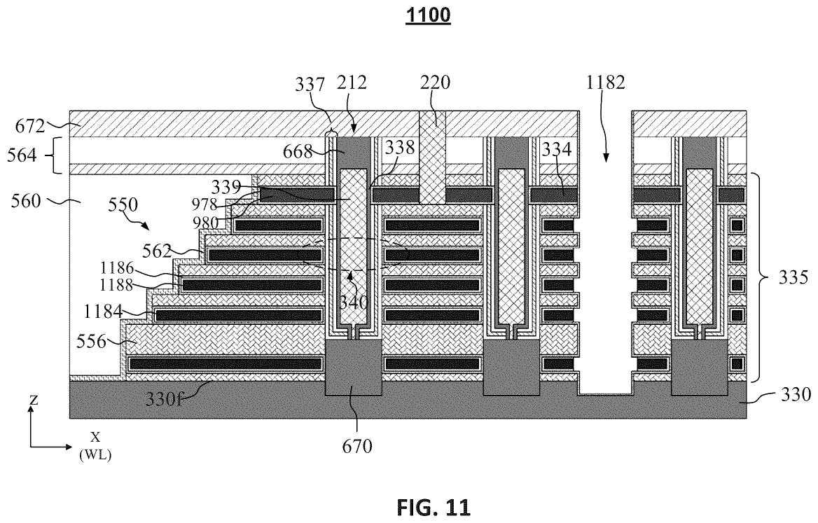

Referring to FIG. 4, at process step S445, a gate line slit (GLS) opening can be formed in the alternating dielectric stack. At process step S450, the second dielectric layers in the alternating dielectric stack can be replaced with second conductive layers to form the film stack of alternating conductive and dielectric layers. A cross-sectional view of an exemplary 3D memory structure 1100 is shown in FIG. 11, according to the process steps S445 and S450.

As shown in FIG. 11, the 3D memory structure 1100 includes a gate line slit (GLS) opening 1182 formed in the alternating dielectric stack 554. The GLS opening 1182 penetrates vertically through TSG conductive layer 980 and the alternating dielectric stack 554. In some embodiments, the GLS opening 1182 also penetrates through the capping layer 672 and the top dielectric stack 564. In some embodiments, the GLS opening 1182 extends into the substrate 330. The GLS opening 1182 can be formed by a lithography process and an etching process. The etching process can include any suitable dry etching, wet etching and/or a combination thereof. In the subsequent processes, the GLS opening 1182 can be used to form the slit structure 216 (also referred to as the GLS) as illustrated in FIG. 2. Similar to the GLS 216, the GLS opening 1182 can extend laterally along the WL direction (see FIG. 2).

At process step S450, the second dielectric layers 558 (in FIG. 10) in the alternating dielectric stack 554 and the staircase structure 550 can be removed through the GLS opening 1182 to form lateral tunnels, similar to the process step S430. The lateral tunnels can extend in a lateral direction between adjacent first dielectric layers 556. It is noted that, the term “lateral/laterally” used herein means the plane parallel to the top surface 330f of the substrate 330. The second dielectric layers 558 in the alternating dielectric stack 554 are also referred to as sacrificial layers, and can be removed selectively from between the first dielectric layers 556. In the other words, the etching process of the second dielectric layers 558 can have minimal impact on the first dielectric layers 556. The second dielectric layers 558 can be removed by an isotropic dry etch and/or wet etch. The plasma and/or chemical used in the dry/wet etch can travel vertically and laterally from the GLS opening 1182. In some embodiments, the second dielectric layer 558 can be silicon nitride, and the first dielectric layer 556 can be silicon oxide. In this example, the second dielectric layer 558 can be removed by RIE using one or more etchants of CF4, CHF3, C4F8, C4F6, and CH2F2, etc. In some embodiments, the second dielectric layer 558 can be removed using wet etch, such as phosphoric acid.

In some embodiments, the second dielectric layers 558 can also be removed selectively from the TSG conductive layer 980 such that there is no or very little etching of the TSG conductive layer 980. In some embodiments, the second dielectric layers 558 can also be removed selectively from the TSG dielectric layer 978 such that there is no or very little etching of the TSG dielectric layer 978. In one example, the TSG dielectric layer 978 and the first dielectric layers 556 are silicon oxide.

Next, second conductive layers 1184 can be disposed inside the lateral tunnels through the GLS opening 1182. The second conductive layers 1184 can be disposed in between adjacent first dielectric layers 556. The TSG conductive layer 980, the second conductive layers 1184 and the first dielectric layers 556 can form the film stack 335 of alternating conductive and dielectric layers (as in FIG. 3). As discussed above, the film stack 335 can also include the TSG dielectric layer 978.

In some embodiments, the second conductive layers 1184 can be formed by filling the lateral tunnels with a suitable conductive material. The conductive material for the second conductive layers 1184 can include metal or metal alloys such as tungsten (W), aluminum (Al), titanium (Ti), copper (Cu), cobalt (Co), nickel (Ni), titanium nitride (TiN), tungsten nitride (WN), tantalum (Ta), tantalum nitride (TaN), AlTi, or any combination thereof. In some embodiments, the conductive material for the second conductive layers 1184 can also include poly-crystalline semiconductors, such as poly-crystalline silicon, poly-crystalline germanium, poly-crystalline germanium-silicon and any other suitable material, and/or combinations thereof. In some embodiments, the poly-crystalline material can be incorporated with any suitable n-type or p-type of dopants, such as boron, phosphorous, arsenic, or any combination thereof. In some embodiments, the second conductive layers 1184 can also be amorphous semiconductors such as amorphous silicon. In some embodiments, the conductive material can be disposed using a suitable deposition method such as chemical vapor deposition (CVD) (e.g., LPCVD, PECVD, MOCVD, RTCVD, etc.), physical vapor deposition (PVD), sputtering, evaporation, atomic layer deposition (ALD), or any combination thereof. In some embodiments, the second conductive layers 1184 include a conductive material different from the TSG conductive layer 980. In some embodiments, the second conductive layers 1184 include tungsten (W) deposited by CVD, while the TSG conductive layer 980 includes polycrystalline silicon doped with n-type dopants (e.g., phosphorous).

As described above, by replacing the second dielectric layers 558 with the TSG conductive layer 980 and the second conductive layers 1184, the alternating dielectric stack 554 turns into the film stack 335 of alternating conductive and dielectric layers. Accordingly, the channel structures 666 (in FIG. 10) formed in the alternating dielectric stack 554 become the memory strings 212. The intersections of the memory strings 212 and the film stack 335 form the vertically stacked memory cells 340. As discussed above, in some embodiments, the film stack 335 and the memory strings 212 also include the TSG dielectric layer 978.

It should be understood that although the film stack 335 here is formed by a replacement method (i.e., replacing the second dielectric layers 558 with the TSG conductive layer 980 and the second conductive layers 1184), the film stack 335 can also be formed by other approaches, for example, by disposing the TSG conductive layer 980, the second conductive layers 1184 and the first dielectric layers 556 directly over the substrate 330.

In some embodiments, a gate dielectric layer 1186 can be disposed inside the lateral tunnels, prior to disposing the second conductive layers 1184. The gate dielectric layer 1186 can include any suitable insulator, for example, silicon oxide, silicon nitride, silicon oxynitride, and/or any suitable combinations thereof. The gate dielectric layer 1186 can also include high-k dielectric materials, such as hafnium oxide, zirconium oxide, aluminum oxide, tantalum oxide, lanthanum oxide, and/or any combination thereof. The gate dielectric layer 1186 can be disposed by one or more suitable deposition processes, such as CVD, PVD, and/or ALD. The gate dielectric layer 1186 can include a dielectric material different or same as the TSG dielectric layer 978.

In some embodiments, a first adhesion layer 1188 can be disposed on the gate dielectric layer 1186, prior to disposing the second conductive layers 1184. The first adhesion layer 1188 can be used to promote adhesion between the gate dielectric layer 1186 and the second conductive layers 1184. The first adhesion layer 1188 can include, for example, tantalum nitride (TaN) and/or titanium nitride (TiN).

In some embodiments, etching and cleaning processes can be used to remove excess conductive materials of the second conductive layer 1184 on sidewalls of the GLS opening 1182. As such, each of the second conductive layers 1184 and the TSG conducive layer 980 can be electrically isolated from each other. In some embodiments, the second conductive layers 1184 can be recessed back from sidewalls of the GLS opening 1182. In some embodiments, excess conductive materials on top of the capping layer 672 can also be removed, for example, by CMP or a dry/wet etching process.

At the completion of the process step S450, the film stack 335 of alternating conductive and dielectric layers includes two sub-stacks. A top stack of the film stack 335 includes the TSG conductive layer 980 and the first dielectric layer 556, and a bottom stack of the film stack 335 includes the first dielectric layers 556 and the second conductive layers 1184.

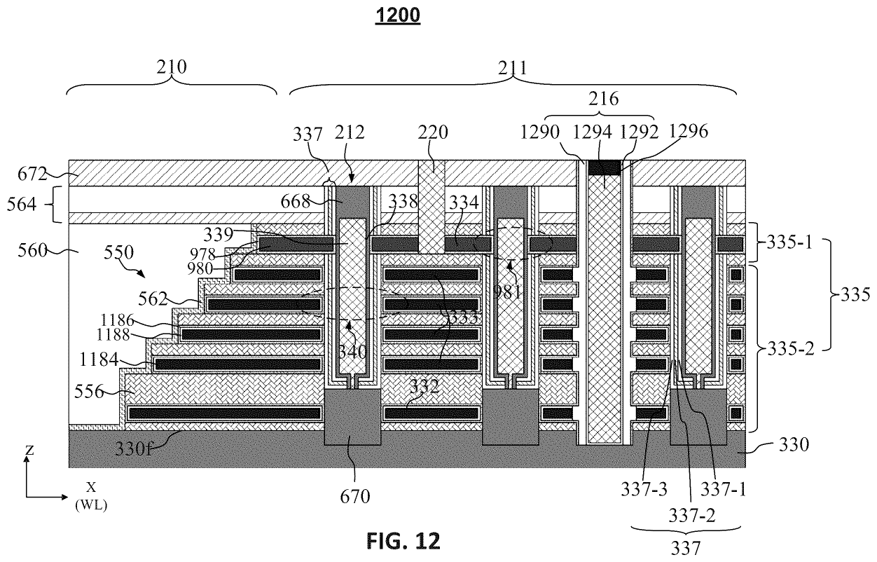

Referring to FIG. 4, at process step S455, a GLS conductive core can be disposed inside the GLS opening to form a GLS. A cross-sectional view of an exemplary 3D memory device 1200 is shown in FIG. 12, according to the process step S455.

As shown in FIG. 12, the 3D memory device 1200 includes a GLS 216 (also referred to as the slit structure 216 as shown in FIGS. 2-3). The GLS 216 penetrates vertically through the film stack 335 of alternating conductive and dielectric layers and extends into the substrate 330.

The GLS 216 includes a GLS isolation layer 1290 disposed on a sidewall of the GLS opening 1182 (in FIG. 11). The GLS isolation layer 1290 covers sidewalls of the second conductive layers 1184 that are exposed inside the GLS opening 1182. The GLS isolation layer 1290 can include any suitable insulator, for example, silicon oxide, silicon nitride, silicon oxynitride, boron or phosphorus doped silicon oxide, carbon-doped oxide (CDO or SiOC or SiOC:H), or fluorine doped oxide (SiOF), or any combination thereof. The GLS isolation layer 1290 can be deposited by using, for example, ALD, CVD (e.g., PECVD, RTCVD, LPCVD, etc.), PVD, sputtering, evaporating, or any other suitable film deposition techniques.

In some embodiments, a portion of the second conductive layer 1184 disposed on a bottom of the GLS opening 1182 can be removed by a dry or wet etching process, prior to the deposition of the GLS isolation layer 1290. As such, a portion of the substrate 330 can be exposed inside the GLS opening 1182, before the deposition of the GLS isolation layer 1290. In some embodiments, a portion of the GLS isolation layer 1290 on the bottom of the GLS opening 1182 can also be removed by a dry or wet etching process, after the deposition of the GLS isolation layer 1290 to expose the portion of the substrate 330 inside the GLS opening 1182.

The GLS 216 also includes a GLS conductive core 1294 disposed inside the GLS opening 1182. The GLS conductive core 1294 fills the GLS opening 1182 with a conductive material. The GLS conductive core 1294 can contact the exposed portion of the substrate inside the GLS opening 1182 to form an electrical connection with the substrate 330.

In some embodiments, the conductive core 1294 can include metal or metal alloys such as tungsten (W), aluminum (Al), titanium (Ti), copper (Cu), cobalt (Co), nickel (Ni), titanium nitride (TiN), tungsten nitride (WN), tantalum (Ta), tantalum nitride (TaN), AlTi, or any combination thereof. In some embodiments, the conductive core 1294 can also include poly-crystalline semiconductors, such as poly-crystalline silicon, poly-crystalline germanium, poly-crystalline germanium-silicon and any other suitable material, and/or combinations thereof. In some embodiments, the poly-crystalline material can be incorporated with any suitable n-type or p-type of dopants, such as boron, phosphorous, arsenic, or any combination thereof. In some embodiments, the conductive core 1294 can also include amorphous semiconductors such as amorphous silicon. In some embodiments, the conductive core 1294 can also include metal silicide, such as WSix, CoSix, NiSix, TiSix, or AlSix, etc. In some embodiments, the conductive core 1294 can include any combination of the conductive material aforementioned. The conductive core 1294 can be disposed using any suitable deposition method such as CVD (e.g., LPCVD, RTCVD, PECVD, etc.), PVD, ALD, sputtering, evaporation, plating, or any combination thereof. In some embodiments, the conductive core 1294 includes tungsten (W) deposited by CVD.

In some embodiments, the GLS 216 can also include a second adhesion layer 1292 disposed on a sidewall of the GLS isolation layer 1290 in the GLS opening 1182. The second adhesion layer 1292 can be used to promote adhesion between the GLS isolation layer 1290 and the GLS conductive core 1294. In some embodiments, the second adhesion layer 1292 can contact the exposed portion of the substrate 330 inside the GLS opening 1182, where the second adhesion layer 1292 can promote adhesion between the GLS conductive core 1294 and the substrate 330. The second adhesion layer 1292 can include a thin conductive film, for example, tantalum nitride (TaN) and/or titanium nitride (TiN).

In some embodiments, a GLS contact structure 1296 can be formed on a top portion of the GLS 216, in contact with the GLS conductive core 1294 at an end farther away from the substrate 330. First, the GLS conductive core 1294 can be recessed down by a dry or wet etching process to form a cavity in the top. Then, a conductive material can be disposed in the cavity. The GLS contact structure 1296 can include any suitable conductive material, for example, tungsten, cobalt, copper, aluminum, titanium, nickel, titanium nitride, tungsten nitride, tantalum, tantalum nitride, AlTi, or any combination thereof.

In some embodiments, the GLS contact structure 1296, the GLS conductive core 1294, the second adhesion layer 1292 and the GLS isolation layer 1290 located outside the GLS opening 1182 can be removed by a dry or wet etching process and/or CMP. As a result, the GLS 216 can be coplanar with the capping layer 672.

As discussed previously, the GLS 216 can divide a memory block into multiple functional units (e.g., memory fingers 218 in FIG. 2). The GLS 216 can also provide mechanic support in the channel structure region 211. The GLS 216 can provide electrical connection to the substrate 330 or an array common source (not shown in FIG. 12). In some embodiments, the GLS 216 can be used for electrical connection with peripheral circuits fabricated on the substrate 330.

The present disclosure also provides a 3D memory device, according to some embodiments. The structure of the 3D memory device is illustrated in FIG. 12, and can be summarized as following.

The 3D memory device 1200 includes the film stack 335 of alternating conductive and dielectric layers, having a top stack 335-1 and a bottom stack 335-2. The top stack 335-1 includes with one or more of the TSG conductive layers 980 (also referred to as the first conductive layer) and one or more of the first dielectric layers 556. The first conductive layers 980 and the first dielectric layers 556 alternatingly stacked on the bottom stack 335-2, in a first direction perpendicular to the substrate 330. The bottom stack 335-2 includes a plurality of the first dielectric layers 556 and a plurality of the second conductive layers 1184, where the first dielectric layers 556 and the second conductive layers 1184 alternatingly stacked on the substrate 330, in the first direction. It is noted that the top stack 335-1 and the bottom stack 335-2 can include different dielectric layers. For example, the top stack 335-1 can include a third dielectric layer different from the first dielectric layer 556, where the third dielectric layers and the first conductive layers 980 can alternatingly stacked on the bottom stack 335-2. The film stack 335 extends in a surface parallel to the front surface 330f of the substrate 330. In some embodiments, the film stack 335 can also include other materials or layers. For example, there can be one or more dielectric layers disposed between the top stack 335-1 and the bottom stack 335-2.

The first dielectric layer 556 includes any suitable insulating materials, for example, silicon oxide, silicon oxynitride, silicon nitride, TEOS or silicon oxide with F-, C-, N-, and/or H-incorporation. The first dielectric layers 556 can have the same thickness or different thicknesses, which can be in a range between 10 nm to 500 nm. In some embodiments, the first dielectric layer 556 can be silicon oxide with a thickness about 25 nm.

The first conductive layers 980 and the second conductive layers 1184 can include any suitable metal or metal alloys such as tungsten (W), aluminum (Al), titanium (Ti), copper (Cu), cobalt (Co), nickel (Ni), titanium nitride (TiN), tungsten nitride (WN), tantalum (Ta), tantalum nitride (TaN), AlTi, or any combination thereof. The first conductive layers 980 and the second conductive layers 1184 can include poly-crystalline semiconductors, such as poly-crystalline silicon, poly-crystalline germanium, poly-crystalline germanium-silicon and any other suitable material, and/or combinations thereof. In some embodiments, the poly-crystalline material can be incorporated (i.e., doped) with any suitable n-type or p-type of dopants, such as boron, phosphorous, arsenic, or any combination thereof. In some embodiments, the first conductive layers 980 and the second conductive layers 1184 can also include amorphous semiconductors such as amorphous silicon, or any combination of the conductive materials mentioned above. The first conductive layers 980 and the second conductive layers 1184 can have the same or different conductive material. The first conductive layers 980 and the second conductive layers 1184 each can have the same thickness or different thicknesses, which can be in a range between 10 nm to 500 nm. In some embodiments, the second conductive layers 1184 include W with a thickness about 35 nm and the first conductive layers 980 include phosphorus doped polycrystalline silicon with a thickness about 50 nm.

The film stack 335 can also include the gate dielectric layer 1186 surrounding the second conductive layer 1184 in the bottom stack 335-2 and include the TSG dielectric layer 978 surrounding the first conductive layer 980 in the top stack 335-1. The gate dielectric layer 1186 and the TSG dielectric layer 978 can include any suitable insulator, for example, silicon oxide, silicon oxynitride, and/or any suitable combinations thereof. The gate dielectric layer 1186 and the TSG dielectric layer 978 can also include high-k dielectric materials, such as hafnium oxide, zirconium oxide, aluminum oxide, tantalum oxide, lanthanum oxide, and/or any combination thereof.

In the bottom stack 335-2, the gate dielectric layer 1186 contacts with the second conductive layer 1184 and a portion of the memory film 337, where the portion of the memory film 337 contact the channel layer 338. As discussed previously, the memory film 337 includes a storage layer, which includes a charge trapping dielectric material. The charges trapped (or stored) in the storage layer can shift the threshold voltage in the corresponding channel layer. In contrast, in the top stack 335-1, the TSG dielectric layer 978 contacts the TSG conductive layer 980 and a portion of the channel layer 338. Different from the memory film 337 (e.g., the storage layer), the TSG dielectric layer 978 includes a dielectric material that has less number of charge traps, such that the threshold voltage shift can be minimized in the channel layer 338. In some embodiments, in the top stack 335-1, the TSG conductive layer 980 and/or the TSG dielectric layer 978 penetrates laterally at least into the charge trapping layer 337-2 of the memory film 337 to separate the charge trapping layer 337-2 along a second direction parallel to the substrate 330.

In some embodiments, the film stack 335 can also include the first adhesion layer 1188 sandwiched in between the gate dielectric layers 1186 and the second conductive layers 1184. In some embodiments, the film stack 335 can also include the first adhesion layer 1188 sandwiched in between the TSG dielectric layers 978 and the first conductive layers 980. The first adhesion layer 1188 can be used to promote adhesion between the gate dielectric layer 1186 and the second conductive layers 1184, and/or between the TSG dielectric layers 978 and the first conductive layers 980. The first adhesion layer 1188 can include, for example, tantalum nitride (TaN) and/or titanium nitride (TiN).

The 3D memory device 1200 also include the staircase structure 550, formed in the film stack 335 in the staircase region 210. The staircase structure 550 includes a plurality of staircase steps. The staircase step, or a “staircase layer”, refers to a layer stack with the same lateral dimension, parallel to the first conductive layers 980, the second conductive layers 1184 and the first dielectric layers 556. Each of the staircase steps terminates at a shorter length than the staircase step underneath.

The 3D memory device 1200 also includes the insulating layer 560 disposed on the staircase structure 550 and the film stack 335. The insulating layer 560 includes silicon oxide, silicon oxynitride, silicon nitride, TEOS, spin-on-glass, low-k dielectric material, such as carbon-doped oxide (CDO or SiOC or SiOC:H), or fluorine doped oxide (SiOF), etc. In some embodiments, the insulating layer 560 can have a planar surface over the staircase structure 550.

The 3D memory device 1200 also includes a plurality of memory strings 212 in the channel structure region 211, wherein the memory strings 212 penetrate through the film stack 335 in the first direction. In some embodiments, the memory strings extend further into the substrate 330.

The 3D memory device 1200 includes a plurality of vertically stacked memory cells 340, formed at the intersections of the second conductive layers 1184 in the lower stack 335-2 and the memory strings 212. The second conductive layers 1184 can function as the word lines 333 (in FIG. 3) to address the memory cells 340. The second conductive layers 1184 located at a bottom portion (i.e., closer to the substrate 330) of the second stack 335-2 can function as the lower select gate (LSG) 332 (in FIG. 3) to switch on or off of lower select transistors of the memory string 212 such that the memory string 212 can be electrically connected or disconnected from the substrate 330 or the array common source (not shown in FIG. 12) in the substrate 330.

In some embodiments, the memory strings 212 can have a cylindrical shape. The memory string 212 can include the core filling film 339 in a center, where the core filling film 339 can be surrounded by the channel layer 338. The core filling film 339 can include any suitable insulator, for example, silicon oxide, silicon nitride, silicon oxynitride, spin-on-glass, boron or phosphorus doped silicon oxide, carbon-doped oxide (CDO or SiOC or SiOC:H), fluorine doped oxide (SiOF), or any combination thereof. The channel layer 338 can include any suitable semiconductor such as polycrystalline silicon with a thickness in a range from about 10 nm to about 30 nm.

A bottom portion of the memory string 212 extending through the bottom stack 335-2, where the memory cells 340 are formed, also includes the memory film 337 covering a sidewall of the channel layer 338, i.e., surrounding the channel layer 338. The memory film 337 can be a composite layer including the tunneling layer 337-1, the storage layer 337-2 (also known as “charge trapping layer”), and the blocking layer 337-3. In some embodiments, the tunneling layer 337-1, the storage layer 337-2, and the blocking layer 337-3 are arranged along a direction from a center of the memory string 212 toward the outer of the memory string 212 in the above order. The tunneling layer 337-1 can include silicon oxide, silicon nitride, or any combination thereof. The blocking layer 337-3 can include silicon oxide, silicon nitride, high dielectric constant (high-k) dielectrics, or any combination thereof. The storage layer 337-2 can include silicon nitride, silicon oxynitride, silicon, or any combination thereof. In some embodiments, the memory film 337 includes ONO dielectrics (e.g., a tunneling layer including silicon oxide, a storage layer including silicon nitride, and a blocking layer including silicon oxide). In some embodiments, a thickness of the memory film 337 can be in a range from about 10 nm to about 50 nm.

A top portion of the memory string 212 extends through the top stack 335-1, where the top select transistors 981 can be formed at the intersections between the first conductive layer 980, the TSG dielectric layer 978 (and/or the tunneling layer 337-1), and the channel layer 338. The top select transistor 981 does not include the charge trapping layer 337-2 of the memory film 337 at an intersection between the first conductive layer 980 and the channel layer 338. Namely, the charge trapping layer 337-2 is separated by a lateral structure along the second direction parallel to the substrate, where the lateral structure comprises the first conductive layer 980. In some embodiments, the lateral structure further comprises the TSG dielectric layer 978, where the TSG dielectric layer 978 is sandwiched between the TSG conductive layer 980 and a portion of the channel layer 338 in the second direction, and the TSG dielectric layer 978 contacts the charge trapping layer 337-2 and the TSG conductive layer 980 in the first direction. In some embodiments, the lateral structure further comprises the tunneling layer 337-1 of the memory film, where the tunneling layer 337-1 is sandwiched between the TSG conductive layer 980 and the channel layer 338 in the second direction. The intersection between the TSG conductive layer 980 and the channel layer 338 in the second direction forms the top select transistor 981. The top select transistor 981 can be switched on or off by applying a voltage on the first conductive layer 980, which can function as the TSG 334 (in FIG. 3).

In some embodiments, the memory string 212 also include an epitaxial plug 670 at the bottom of the memory string 212. The epitaxial plug 670 can include any suitable semiconductor material, such as silicon, silicon germanium, germanium, gallium arsenide, gallium nitride, III-V compound, or any combination thereof. In some embodiments, the epitaxial plug 670 can also include a polycrystalline semiconductor material, for example, polycrystalline silicon. The epitaxial plug 670 extends through at least one of the second conductive layers 1184 at the bottom portion of the bottom stack 335-2, where the lower select transistors can be formed at the intersections between the epitaxial plug 670 and the at least one of the second conductive layers 1184 at the bottom portion of the bottom stack 335-2. The epitaxial plug 670 can connect to the channel layer 338 of the memory string 212 at a first end and connect to the substrate 330 at a second end, opposite the first end.

In some embodiments, the memory string 212 can also include the channel top plug 668, configured to provide electrical contact to the channel layer 338. Bit lines (not shown in FIG. 12) of the 3D memory device 1200 can address the memory cells 340 through the channel top plug 668. The channel top plug 668 can be amorphous or polycrystalline silicon, and can include metal, metal alloy and/or metal silicide, for example, tungsten, titanium, tantalum, tungsten nitride, titanium nitride, tantalum nitride, nickel silicide, cobalt silicide, tungsten silicide, titanium silicide, or a combination thereof.

In some embodiments, the 3D memory device 1200 also includes the TSG cut 220, extending vertically in the top stack 335-1, in the first direction. The TSG cut 220 extends through the first conductive layers 980, and can be filled with an insulating material such as silicon oxide, silicon nitride, silicon oxynitride, boron or phosphorus doped silicon oxide, carbon-doped oxide (CDO or SiOC or SiOC:H), or fluorine doped oxide (SiOF), or any combination thereof. The TSG cut 220 can provide electrical isolation between adjacent TSGs 334. By forming the TSG cut 220, the first conductive layer 980 can be divided into two or more TSGs 334 that can be controlled independently.

The 3D memory device 1200 also includes the GLS 216 penetrating vertically through the film stack 335, in the first direction. In some embodiments, the GLS 216 extends further into the substrate 330. The GLS 216 can include the GLS conductive core 1294 and the GLS isolation layer 1290 that covers a sidewall of the GLS conductive core 1294. In some embodiments, the GLS conductive core 1294 contacts the substrates 330 and can provide electrical connection to the substrate 330.

The GLS isolation layer 1290 can include any suitable insulating material, for example, silicon oxide, silicon nitride, silicon oxynitride, TEOS, etc. The GLS conductive core 1294 can include any suitable conductive material, for example, tungsten (W), aluminum (Al), titanium (Ti), copper (Cu), cobalt (Co), nickel (Ni), titanium nitride (TiN), tungsten nitride (WN), tantalum (Ta), tantalum nitride (TaN), AlTi, or any combination thereof. In some embodiments, the conductive core 1294 can also include poly-crystalline semiconductors, such as poly-crystalline silicon, poly-crystalline germanium, poly-crystalline germanium-silicon and any other suitable material, and/or combinations thereof. In some embodiments, the poly-crystalline material can be incorporated with any suitable n-type or p-type of dopants, such as boron, phosphorous, arsenic, or any combination thereof. In some embodiments, the conductive core 1294 can also include amorphous semiconductors such as amorphous silicon. In some embodiments, the conductive core 1294 can also include metal silicide, such as WSix, CoSix, NiSix, TiSix, or AlSix, etc. In some embodiments, the conductive core 1294 can include any combination of the conductive material aforementioned. In some embodiments, the conductive core 1294 includes tungsten (W).

In some embodiments, the GLS 216 can also include the second adhesion layer 1292 sandwiched between the GLS conductive core 1294 and substrate 330, and sandwiched between the GLS conductive core 1294 and the GLS isolation layer 1290. The second adhesion layer 1292 can be used to promote adhesion between the GLS conductive core 1294 and the substrate 330 and/or the GLS isolation layer 1290. The second adhesion layer 1292 can include a thin conductive film, for example, tantalum nitride (TaN) and/or titanium nitride (TiN).

In some embodiments, the GLS 216 further includes the GLS contact structure 1296, contacting the GLS conductive core 1294 on the top (an end further away from the substrate). The GLS contact structure 1296 can include any suitable conductive material, for example, tungsten, cobalt, copper, aluminum, titanium, nickel, titanium nitride, tungsten nitride, tantalum, tantalum nitride, AlTi, or any combination thereof.

In some embodiments, the 3D memory device 1200 also includes the top dielectric stack 564 disposed on the insulating layer 560 and the film stack 335. In some embodiments, the 3D memory device 1200 further includes the capping layer 672 disposed on the top dielectric stack 564, covering the memory strings 212. In some embodiments, the memory strings 212 also penetrate through the top dielectric stack 564 and are coplanar with the top dielectric stack 564. In some embodiments, the GLS 216 and the TSG cut 220 also penetrate through the capping layer 675 and the top dielectric stack 564, and are coplanar with the capping layer 672.

As described above, the channel layer 338 of the memory string 212 can be connected to the bit line through the channel top plug 668, where the connection can be controlled by the top select transistor 981. In the present disclosure, the top select transistor 981 is configured as a MOSFET, where the TSG dielectric layer 978 can be the gate dielectric of the MOSFET, and at least the charge trapping layer 337-2 of the memory film 337 is removed at the intersection between the first conductive layer 980 and the channel layer 338 along the second direction. While the charge trapping layer 337-2 can provide charge trapping and storage for the memory cells 340 such that threshold voltages of the memory cells 340 can shift according to the voltages applied on the word lines 333, such threshold voltage shift for the top select transistor 981 is not desirable. By removing the charge trapping layer 337-2 between the first conductive layer 980 and the channel layer 338, the switching property of the top select transistor 981 can be improved. The TSG dielectric layer 978 can include different materials from the storage layer (or charge trapping layer) 337-2 of the memory film 337. Similarly, the first conductive layer 980 can also include different materials from the second conductive layer 1184. As such, the top select transistor 981 can be optimized, independently from the memory cells 340.

It is noted that arrangement or layout of the TSG cut 220 and the GLS 216 in FIG. 12 is illustrated only as an example, and should not be so limiting. As shown in FIG. 2, the GLS 216 can extend along WL direction in a surface parallel to the top surface 330f of the substrate 330. The GLS 216 can divide the second conductive layers 1184 into multiple electrodes (e.g., word lines 333) that are electrically isolated from each other and can be controlled independently. Accordingly, the GLS 216 can divide a memory array into, for example, multiple memory fingers 218, where the memory strings 212 in the same memory finger 218 can share the same word line 333 and the memory strings 212 in different memory fingers 218 can be controlled by separate word lines 333.

The TSG cut 220 can extend along WL direction in a surface parallel to the top surface 330f of the substrate 330. The TSG cut 220 can divide the first conductive layers 980 into multiple electrodes (e.g., TSG 334) that are electrically isolated from each other and can be controlled independently. Thus, the TSG cut 220 can further divide each memory finger 218 into multiple memory slices 224, where the memory strings 212 in the same memory slice 224 can be controlled by the same TSG 334 and the memory strings 212 in different memory slices 224 can be controlled by separate TSG 334. As such, memory strings 212 in a memory array can be addressed in smaller units during programming and reading operations. Performance of the 3D NAND memory can be improved accordingly.

In summary, the present disclosure provides a method for forming a three-dimensional (3D) memory device. The method includes the following steps: disposing an alternating dielectric stack over a substrate, wherein the alternating dielectric stack comprises first dielectric layers and second dielectric layers alternatingly stacked on the substrate; forming a channel structure penetrating through the alternating dielectric stack in a first direction perpendicular to the substrate, wherein the channel structure comprises a charge trapping layer extending in the first direction; removing at least one second dielectric layer at a top portion of the alternating dielectric stack to form a top select gate (TSG) cut tunnel and to expose a portion of the charge trapping layer in a second direction parallel to the substrate; removing the exposed portion of the charge trapping layer inside the TSG cut tunnel; and disposing a TSG conductive layer inside the TSG cut tunnel.

The present disclosure also provides a three-dimensional (3D) memory device. The 3D memory device includes a film stack having a bottom stack and a top stack. The bottom stack includes first dielectric layers and second conductive layers alternatingly stacked on a substrate, and the top stack includes a first conductive layer stacked on the bottom stack. The 3D memory device also includes a memory string penetrating through the film stack in a first direction perpendicular to the substrate, wherein the memory string includes s a charge trapping layer extending in the first direction. The charge trapping layer is separated along a second direction parallel to the substrate by a lateral structure comprising the first conductive layer.

The foregoing description of the specific embodiments will so fully reveal the general nature of the present disclosure that others can, by applying knowledge within the skill of the art, readily modify and/or adapt, for various applications, such specific embodiments, without undue experimentation, and without departing from the general concept of the present disclosure. Therefore, such adaptations and modifications are intended to be within the meaning and range of equivalents of the disclosed embodiments, based on the disclosure and guidance presented herein. It is to be understood that the phraseology or terminology herein is for the purpose of description and not of limitation, such that the terminology or phraseology of the present specification is to be interpreted by the skilled artisan in light of the disclosure and guidance.

Embodiments of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections can set forth one or more but not all exemplary embodiments of the present disclosure as contemplated by the inventor(s), and thus, are not intended to limit the present disclosure and the appended claims in any way.

The breadth and scope of the present disclosure should not be limited by any of the above-described exemplary embodiments, but should be defined only in accordance with the following claims and their equivalents.

What is claimed is:

1. A method for forming a three-dimensional (3D) memory device, comprising:
disposing an alternating dielectric stack comprising first dielectric layers and second dielectric layers alternatingly stacked on a substrate;
forming a channel structure penetrating through the alternating dielectric stack in a first direction perpendicular to the substrate, wherein the channel structure comprises a charge trapping layer extending in the first direction;
removing at least one second dielectric layer at a top portion of the alternating dielectric stack to form a top select gate (TSG) cut tunnel and to expose a portion of the charge trapping layer in a second direction parallel to the substrate;
removing the exposed portion of the charge trapping layer inside the TSG cut tunnel; and
disposing a TSG conductive layer inside the TSG cut tunnel.

2. The method of claim 1, further comprising:
forming a TSG cut opening that extends into the at least one second dielectric layer at the top portion of the alternating dielectric stack in the first direction; and
removing the at least one second dielectric layer through the TSG cut opening.

3. The method of claim 2, further comprising:
disposing an insulating material inside the TSG cut opening to form a TSG cut, wherein the TSG cut separates the TSG conductive layer into top select gates that are electrically isolated from each other.

4. The method of claim 1, further comprising:
prior to disposing the TSG conductive layer, disposing a TSG dielectric layer comprising less charge traps than the charge trapping layer.

5. The method of claim 4, wherein the disposing the TSG dielectric layer comprises disposing silicon oxide, silicon oxynitride, or a combination thereof.

6. The method of claim 1, wherein the disposing the TSG conductive layer comprises disposing polycrystalline silicon doped with n-type dopants.

7. The method of claim 1, further comprising:
forming a gate line slit (GLS) opening that penetrates through the alternating dielectric stack in the first direction; and
replacing the second dielectric layers with second conductive layers to form a bottom stack, wherein the bottom stack comprises the second conductive layers and the first dielectric layers alternatingly stacked on the substrate.

8. The method of claim 7, further comprising:
disposing a GLS isolation layer on a sidewall of the GLS opening to form a GLS, wherein the GLS separates the second conductive layers into electrodes that are electrically isolated from each other.

9. The method of claim 8, further comprising:
after disposing the GLS isolation layer, removing a portion of the GLS isolation layer on a bottom of the GLS opening to expose the portion of the substrate inside the GLS opening.

10. The method of claim 8, further comprising:
after disposing the GLS isolation layer, deposing an adhesion layer on a sidewall of the GLS isolation layer in the GLS opening.

11. The method of claim 10, wherein the disposing the adhesion layer comprises disposing at least one of tantalum nitride (TaN) or titanium nitride (TiN).

12. The method of claim 8, further comprising:
after disposing the GLS isolating layer, filling the GLS opening with a GLS conductive core.

13. The method of claim 12, further comprising:
forming a GLS contact structure on a top portion of the GLS, wherein the GLS contact structure in contact with the GLS conductive core at an end farther away from the substrate.

14. The method of claim 13, wherein:
the forming a GLS contact structure on a top portion of the GLS comprises:
removing a portion of the GLS conductive core to form a cavity in the top portion, and
disposing a conductive material in the cavity to form the GLS contact structure.

15. The method of claim 7, wherein replacing the second dielectric layers with the second conductive layers comprises:
removing the second dielectric layers from the GLS opening to form lateral tunnels in the second direction in between the first dielectric layers; and
disposing the second conductive layers inside the lateral tunnels, wherein the second conductive layers comprise a conductive material different from the TSG conductive layer.

16. The method of claim 15, wherein the disposing the second conductive layers comprises disposing tungsten, aluminum, titanium, cobalt, nickel, titanium nitride, tungsten nitride, tantalum, tantalum nitride, or any combination thereof.

17. The method of claim 15, wherein removing the second dielectric layers comprises etching the second dielectric layers selectively to the TSG conductive layer and the first dielectric layers.

18. The method of claim 1, wherein the forming the channel structure comprises:
forming a channel hole penetrating through the alternating dielectric stack in the first direction; and
disposing a memory film on a sidewall of the channel hole, comprising:
disposing, sequentially, a blocking layer, the charge trapping layer and a tunneling layer, wherein the charge trapping layer comprises a charge trapping dielectric material;
disposing a channel layer on a sidewall of the memory film; and
filling the channel hole with a core filling film.

19. The method of claim 18, wherein disposing, sequentially, the blocking layer, the charge trapping layer and the tunnel layer comprises disposing, sequentially, silicon oxide, silicon nitride and silicon oxide.

20. The method of claim 18, further comprising:
removing a portion of the memory film at a bottom of the channel hole before disposing the channel layer on the sidewall of the memory film.
